(19) United States
(12) Patent Application Publication
(10) Pub. No.: US 2015/0001735 A1
(43) Pub. Date: Jan. 1, 2015

(54) MULTIPATTERNING VIA SHRINK METHOD USING ALD SPACER

(71) Applicants: STMicroelectronics, Inc., Coppell, TX (US); International Business Machines Corporation, Armonk, NY (US)

(72) Inventors: Yann Mignot, Albany, NY (US); Hsueh-Chung Chen, Cohoes, NY (US)

(21) Appl. No.: 14/320,326

(22) Filed: Jun. 30, 2014

Related U.S. Application Data
(60) Provisional application No. 61/840,958, filed on Jun. 28, 2013.

(51) Int. Cl. H01L 23/522; H01L 21/3065; H01L 21/768

(52) U.S. Cl. CPC H01L 23/5226; H01L 21/76897; H01L 21/3065
USPC 257/774; 438/637

(57) ABSTRACT

A method of manufacturing a semiconductor device an include forming an first low temperature oxide (LTO) layer over an organic planarization layer (OPL) layer, forming a primary via pattern in the LTO layer to partially expose the OPL layer, forming a conformal second LTO layer over the primary via pattern including the first LTO layer and the partially exposed OPL layer, and etching the second LTO layer to form spacers on sidewalls of the primary via pattern in the first LTO layer.

### CROSS-REFERENCE TO RELATED APPLICATION(S) AND CLAIM OF PRIORITY

The present application is related to U.S. Provisional Patent Application No. 61/840,958, filed Jun. 28, 2013, entitled “MULTIPATTERNING VIA SHRINK METHOD USING ALD SPACER”. Provisional Patent Application No. 61/840,958 is assigned to the assignee of the present application and is hereby incorporated by reference into the present application as if fully set forth herein. The present application hereby claims priority under 35 U.S.C. §119(e) to U.S. Provisional Patent Application No. 61/840,958.

### TECHNICAL FIELD

The present disclosure relates to semiconductor processing and fabricating semiconductor integrated circuits and, more specifically, to shrinking the critical dimension of vias and contacts defined by single or multiple patterning techniques.

### BACKGROUND

Semiconductor integrated circuits are manufactured according to specifications which include a minimum feature size known as a “critical dimension”. For example, a critical dimension might be given as 65 nanometers. Much of the work in the semiconductor arts is aimed at producing reliable, low cost semiconductors while shrinking or reducing the critical dimension.

One component in semiconductor circuits is known as a “via”, which is an opening in an insulating layer that forms a conductive path between components (for example, a wiring layer, contacts, or gates). As the critical dimension of gates, wiring layers and other components shrink, so must the critical dimension of the vias.

There is, therefore, an ongoing need in the art for forming improved vias with a reduced critical dimension.

### SUMMARY

A method according to disclosed embodiments can include forming a first low temperature oxide (LTO) layer over an organic planarization layer (OPL) layer, forming a primary via pattern in the LTO layer to partially expose the OPL layer, forming a conformal second LTO layer over the primary via pattern including the first LTO layer and the partially exposed OPL layer, and etching the second LTO layer to form a plurality of spacers on sidewalls of the primary via pattern in the first LTO layer.

A method of processing a semiconductor substrate according to disclosed embodiments can include forming a dielectric layer above a first layer on a substrate, forming a primary via pattern layer disposed above the dielectric layer, etching a primary via pattern in the primary via pattern layer having a plurality of via openings therethrough, the plurality of via openings having a first dimension. The method can continue with forming a conformal secondary via pattern layer above the primary via pattern, etching a secondary via pattern in the secondary via pattern layer to form a plurality of spacers on sidewalls of the plurality of via openings within the primary via pattern in the primary via pattern layer, the plurality of spacers reducing the first dimension of the plurality of via openings to a second dimension, and etching via openings through the dielectric layer using the secondary via pattern.

An integrated circuit structure according to disclosed embodiments can include a substrate containing at least one active semiconductor device, an interlayer dielectric layer over the substrate, a tetraethoxysilane (TEOS) layer over the interlayer dielectric layer, a hard mask layer over the TEOS layer, an OPL, a first LTO) layer over the OPL layer, the first LTO layer defining an original via pattern having a critical dimension, and a second LTO layer over the first LTO layer defining a modified via pattern having a reduced critical dimension.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIGS. 1A through 1F depict a sectional view of an integrated circuit structure showing stages of formation of a via;

FIG. 2 is a high level flow chart illustrating a process of forming a via pattern in accordance with one embodiment of the present disclosure; and

FIG. 3 is a high level flow chart illustrating a process of forming a via pattern in accordance with another embodiment of the present disclosure.

### DETAILED DESCRIPTION

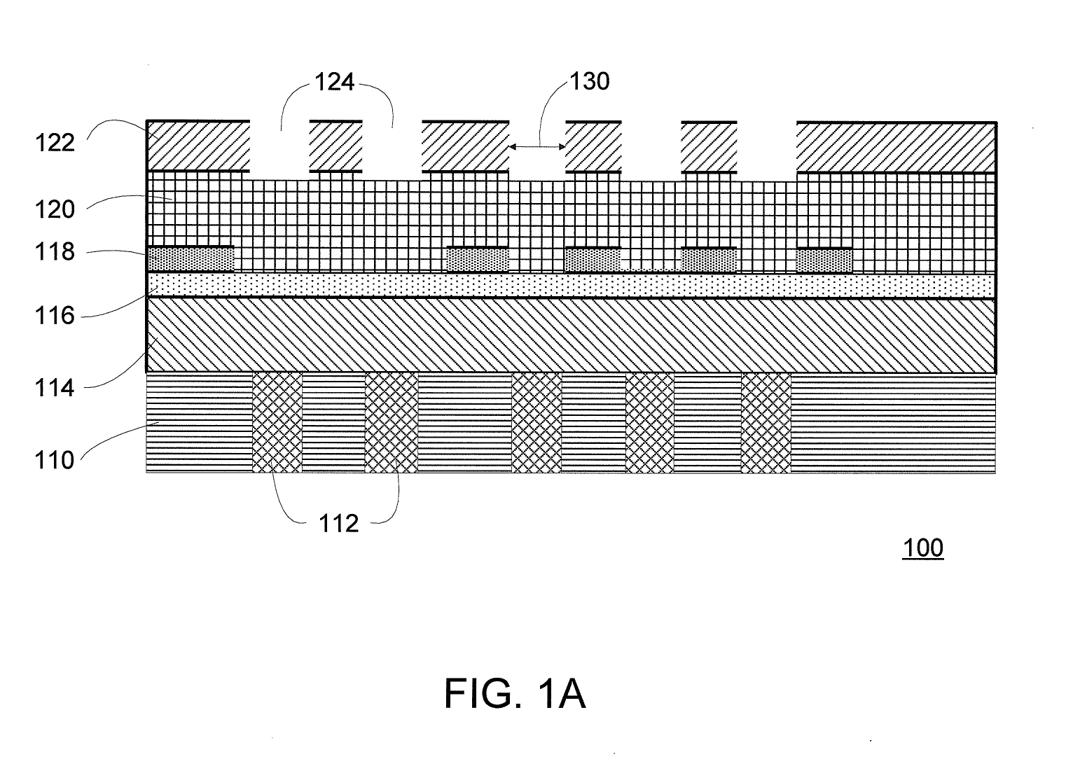

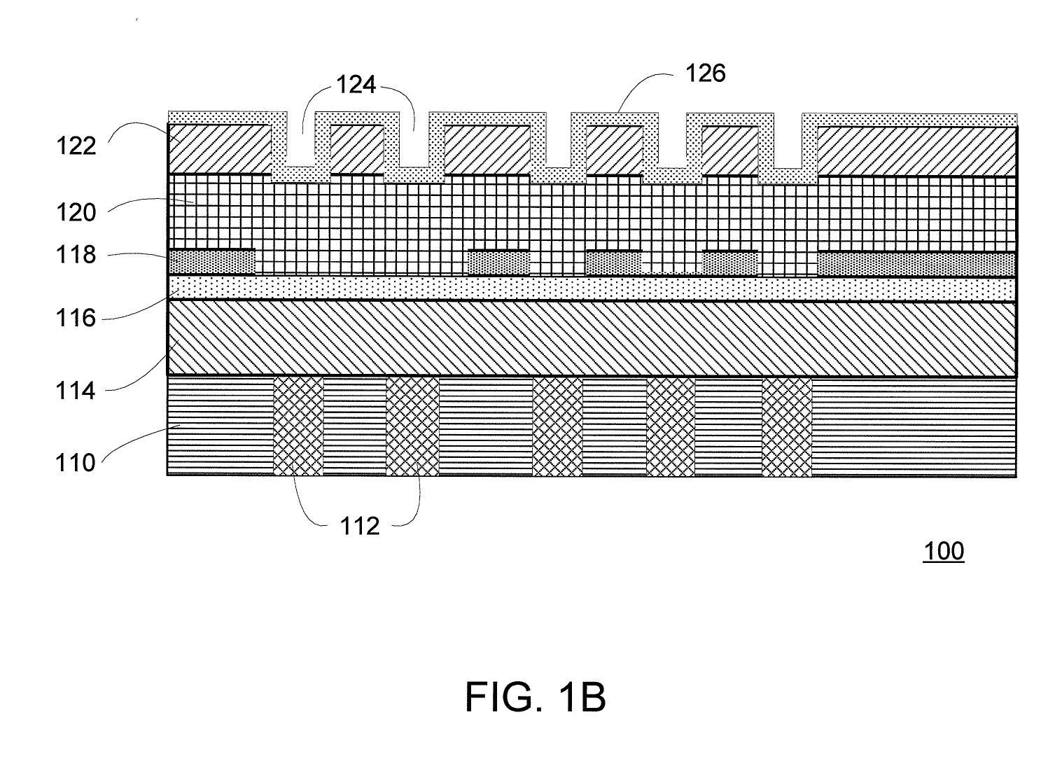

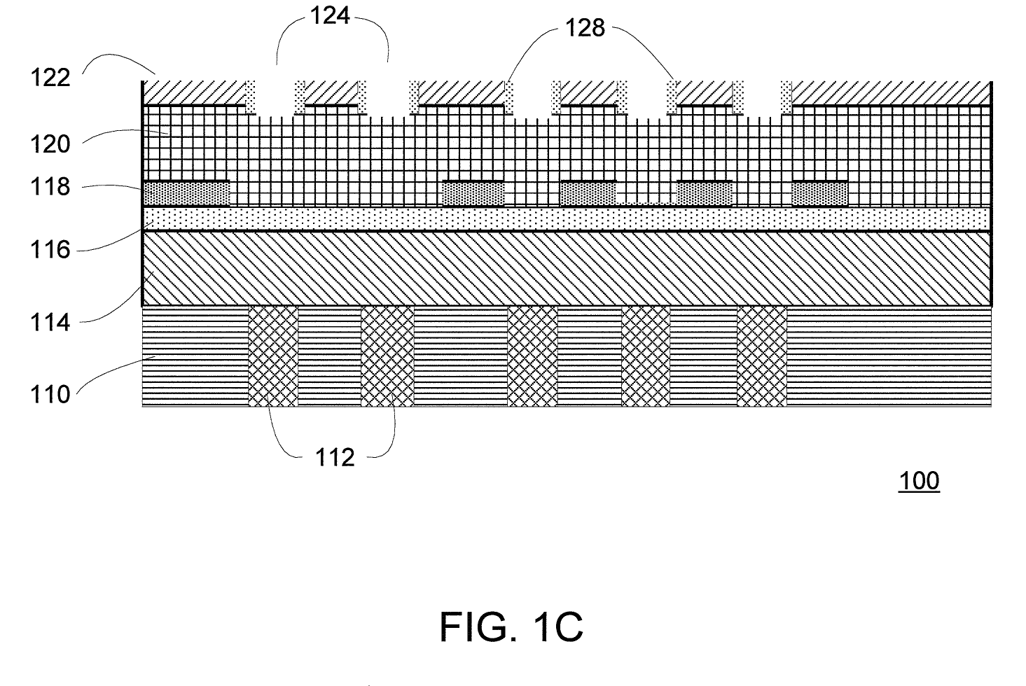

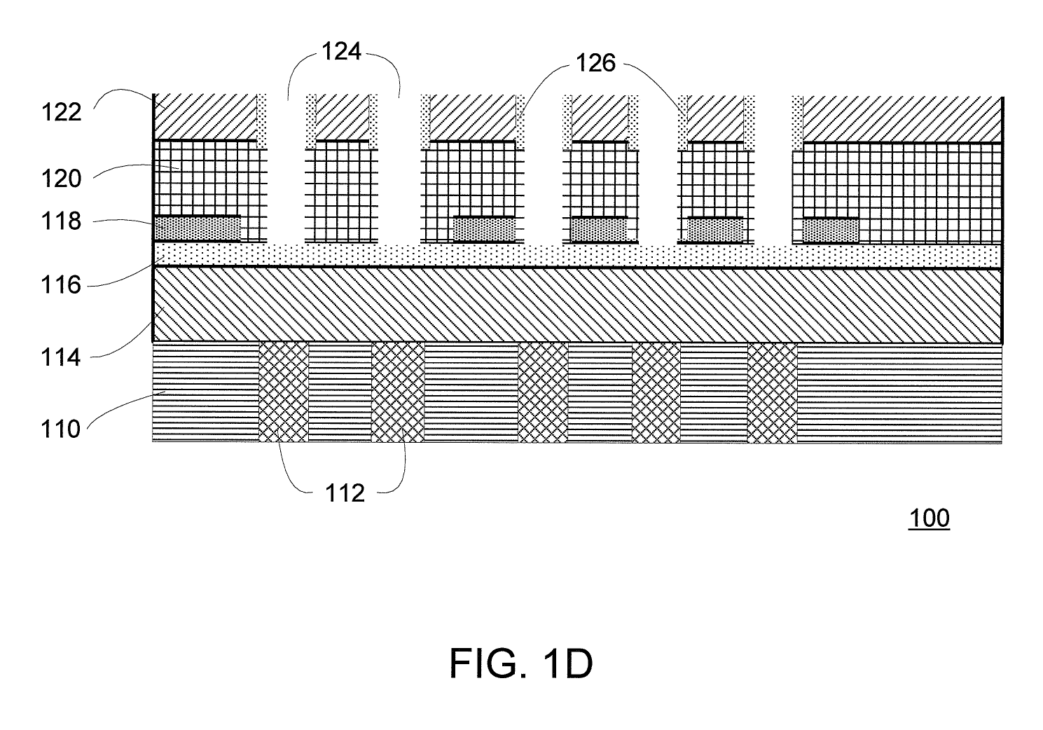

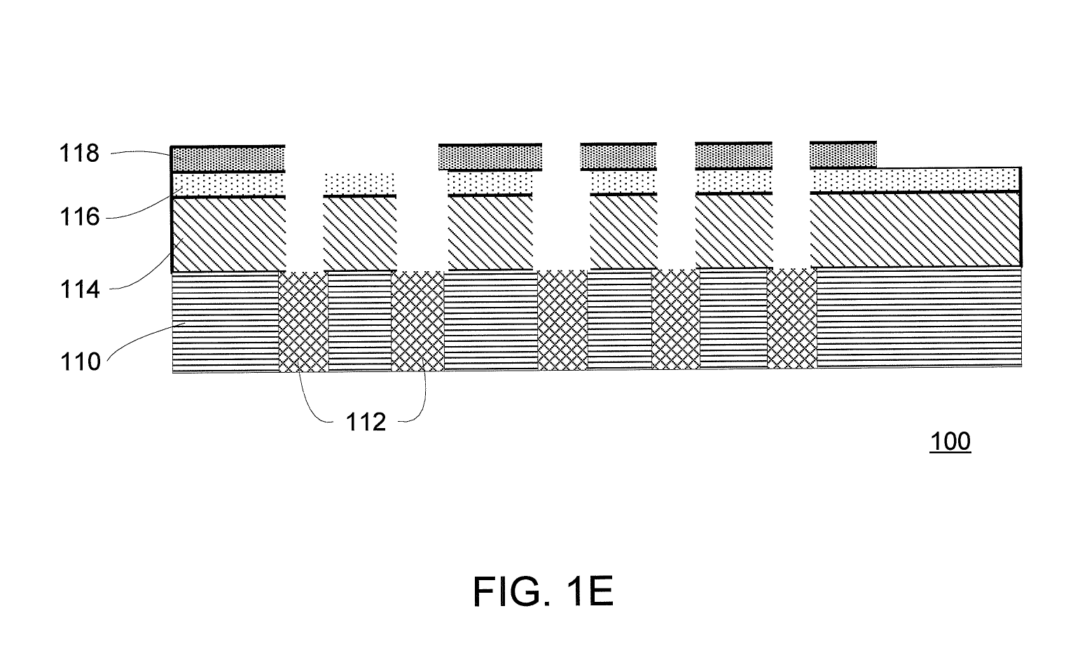

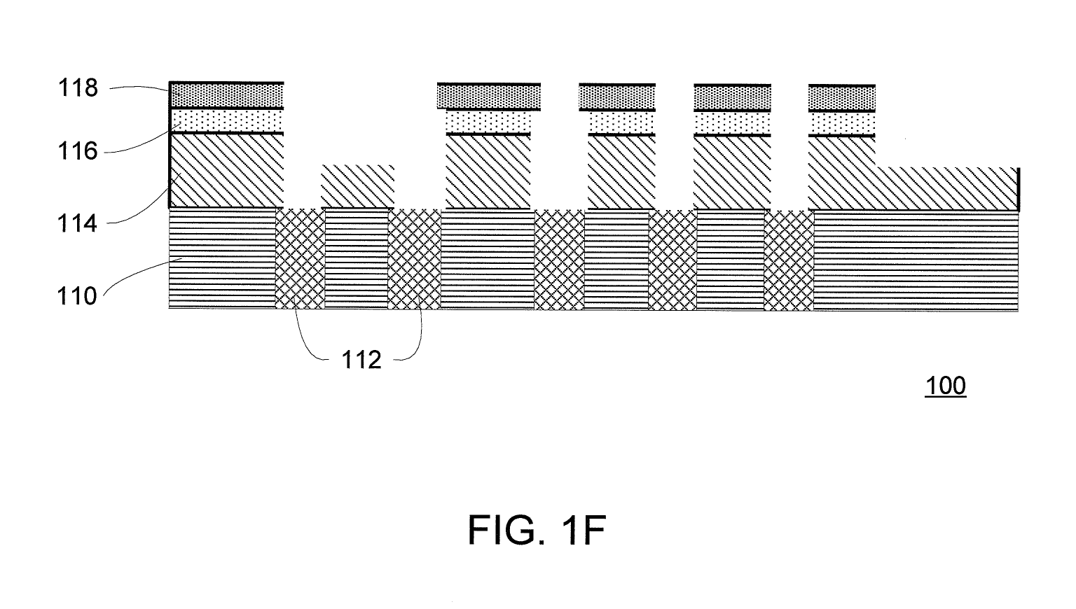

FIGS. 1A through 3, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system.

In the continual push towards reducing the critical dimension (CD) in semiconductor manufacturing, current immersion lithography has reached technical limitations in printing smaller vias. However, with the emergence of the dual and triple via patterning techniques, greater CD shrink is required. This disclosure teaches methods of relaxing lithography constraints to deliver smaller vias and create an efficient process flow to control the CD using an atomic layer deposition (ALD) spacer formation.

Various embodiments in this disclosure teach a double via patterning method. As will be understood by the skilled artisan, the method may be extended to a triple or multiple via patterning method. Rework can be performed in all combinations. The methods may have some transferability to single via patterning schemes, but for cost reasons, these may not be applicable.

In various embodiments in accordance with present disclosure, vias are memorized or patterned in a low temperature oxide (LTO) layer. Rather than beginning with a process of etching the dielectric, for example by reactive-ion etching (RIE), an ALD spacer layer is deposited on the substrate/wafer. The thickness of the ALD spacer layer may be precisely modulated or controlled. While ALD is disclosed herein, the skilled artisan will appreciate that other methods of depositing a conformal thin film layer may be used. The thickness of the ALD spacer layer can be controlled in consideration of the thickness of the LTO memory layer and the desired CD shrink. The first step of the dielectric RIE is to remove much of the ALD spacer layer, thereby creating a spacer on the via sidewall. This spacer will define the new mask and the new CD. The method may be used for round vias and bar vias. After the spacer is created, the via process can progress to the etching of an organic planarization layer (OPL), self-aligned via (SAV) steps, and to the end of the via process (i.e., formation of the conductive vias in the etched pattern). The ALD spacer can be removed during the SAV process.

At the end, the CD can be modulated for the non-SAV direction. Advanced process control (APC) feedforward can be performed based on the lithography CD variation. FIGS. 1A through 1F depict a sectional view of an integrated circuit structure showing stages of formation of one or more vias.

FIG. 1A depicts a sectional view of an integrated circuit structure 100 showing a stage leading to the eventual formation of vias between regions 112 within a layer 110 of a semiconductor substrate and a higher layer. The layer 110 may be an active layer, a contact layer, a middle-of-line layer, or an intermediate wiring layer. FIG. 1A further illustrates an interlayer dielectric layer 114 formed above the layer 110 Layer 114 can serve as an adhesion layer to optimized the adhesion between layer 110 and the TEOS on the top. This layer 114 is going to be removed during a CMP process. A tetraethoxysilane (TEOS) layer 116 can be formed above the dielectric layer 114. A hard mask layer 118, a TEOS layer 116, and an OPL 120 are formed as shown in FIG. 1A. In one embodiment, the hard mask layer 118 is the result of a previous patterning technique to define the illustrated openings or trenches and may be composed of one or more sublayers, including, for example, TiN, TiOₓN_{y}, TiO₂, BN or BCN, and may further comprise an Oxide layer, for example, TEOS, LTO, ALD, or other suitable oxide. base on the trench patterning technique chosen. Finally, an LTO layer 122 may be deposited above the OPL 120. The LTO layer 122 may be formed as an oxide layer, or alternatively, may comprise a nitride layer. The LTO layer 122 forms a primary via pattern layer.

A primary via pattern including a plurality of openings 124 is formed in the LTO layer 122 and define a primary or original critical dimension for the eventual vias. In other words, the width of the openings 124 will be the feature size of the vias in the event reactive ion etching were to be performed at this point in the process to form the vias. However, the original critical dimension of the via pattern in the LTO 122 may be too large for some applications. The primary via pattern may be formed using any suitable method. In one embodiment, for example, the primary via pattern is formed from a multiple operations to memorize the all the via into a single layer 122. Each step of via memorization can be created by depositing photoresist, developing a via pattern in the photoresist, and etching the intermediate stack on top of the LTO layer 122. In some embodiments, the final step can be to use the intermediate layer to transfer in one single operation all the different via into the LTO layer 122. By way of example, the original openings of the via pattern may be about 35-65 nanometers, and a target critical dimension may be between approximately 25-30 nanometers. In other words, the desired CD shrink may be in a range of about 15% to about 55%. In other embodiments, the CD shrink may be in a range of approximately 5 to 10 nanometers.

FIG. 1B depicts a sectional view of the integrated circuit structure 100 showing a stage subsequent to the stage shown in FIG. 1A in the formation of the vias. An ALD spacer layer 126 is formed above the LTO layer 122. The ALD spacer layer 126 may be an oxide formed by ALD, and in one embodiment, may be formed from the same material as the LTO layer 122. Alternatively, the ALD spacer layer 126 may be formed from a nitride. As will be understood, the thickness of the ALD spacer layer 126 (on the sidewalls of the LTO layer 120) reduces the width of the openings 124 in the via pattern. The thickness/dimension of the ALD spacer layer 126 may be chosen in accordance with the desired shrink of the critical dimension of the via pattern.

FIG. 1C depicts a sectional view of the integrated circuit structure 100 showing a stage subsequent to the stage shown in FIG. 1B in the formation of the vias. Portions of the ALD spacer layer 126 are removed/etched to form sidewall spacers 128 on the sidewalls of the openings 124 in the LTO layer 122. As shown, the etch may also expose the OPL 120 at the bottom of the via pattern and the LTO 122 to help to reduce his thickness. As shown, spacers 128 assist in reducing the critical dimension 132 (typo 112) of the openings 124—which now extend through the layers 122 and 120. Any suitable etching or removal technique may be utilized, and in one embodiment, etching is performed by a RIE process.

FIG. 1D depicts a sectional view of the integrated circuit structure 100 showing a stage subsequent to the stage shown in FIG. 1C in the formation of the vias. Here, the via pattern has been extended to the TEOS layer 116 by etching/removing portions of the OPL layer 120. Any suitable etching/removal process may be performed, and in alternative embodiments, O₂, CO₂, CO, SO₂, and COS may be used with some addition of HBr and Helium. As shown, spacers 126 assist in defining or setting the critical dimension of the openings 124—which now extend through the layers 122 and 120.

FIG. 1E depicts a sectional view of the integrated circuit structure 100 showing a stage subsequent to the stage shown in FIG. 1D in the formation of the vias. In this stage, the spacers 126, the layer 122 and the OPL 120 are removed. Any suitable process may be utilized, and in one embodiment, a self-aligned via etch process is performed, and such process may utilize an RIE process.

FIG. 1F depicts a sectional view of the integrated circuit structure 100 showing a stage subsequent to the stage shown in FIG. 1E in the formation of the vias. The final steps in forming the via pattern with a reduced critical dimension may be performed to remove portions of the TEOS layer 116 and interlayer dielectric 114 in non-SAV regions or trench only. In subsequent process steps, a plurality of conductive vias can be formed in the via pattern using any suitable deposition method.

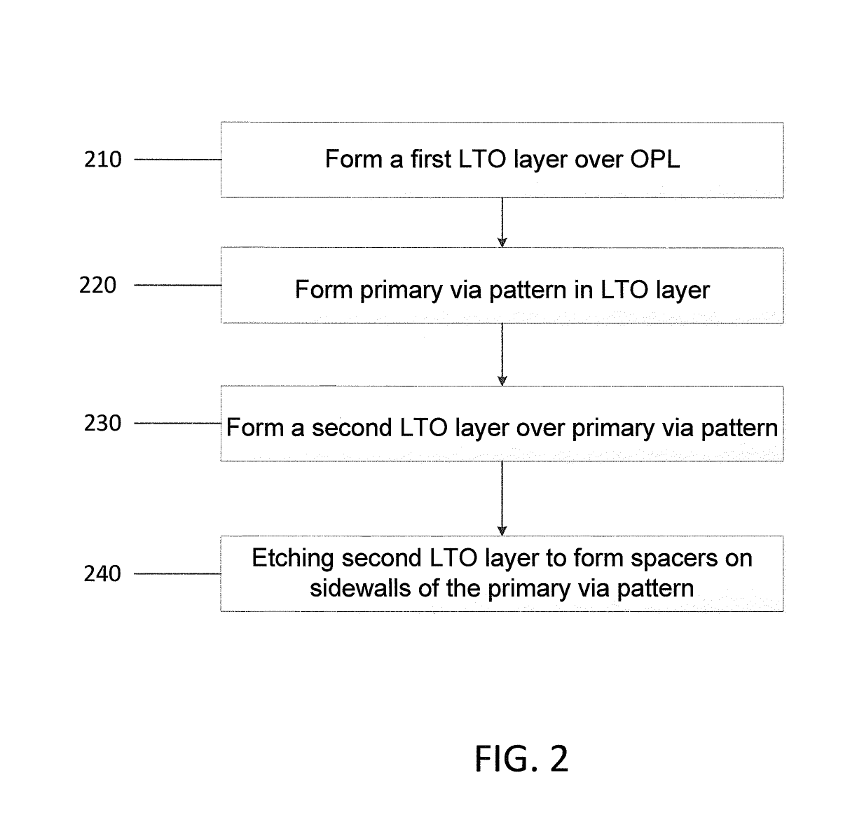

FIG. 2 is a high level flow chart illustrating a process of forming a via pattern in accordance with one embodiment of the present disclosure. In box 210, the process may begin with forming a first LTO layer over an OPL. This can be an oxide layer formed by an ALD process, for example. At box 220 the process can include forming a primary via pattern in LTO layer. This may expose the OPL and have a feature size defining a critical dimension. At box 230 the process can include forming a second LTO layer over primary via pattern. This can include forming a conformal second LTO layer over the primary via pattern including the first LTO layer and the partially exposed OPL.

At box 240 the process can include etching second LTO layer to form spacers on sidewalls of the primary via pattern. This can include etching the second LTO layer using reactive ion etching (RIE) to form a plurality of spacers on sidewalls of the primary via pattern in the first LTO layer. Etching the second LTO layer can form a secondary via pattern which has a reduced critical dimension with respect to the primary via pattern. The secondary via pattern can include self-aligned via (SAV) regions and non-SAV regions. The plurality of spacers on sidewalls of the original via pattern can reduce the size of openings in the primary via pattern by about 15% to about 55%.

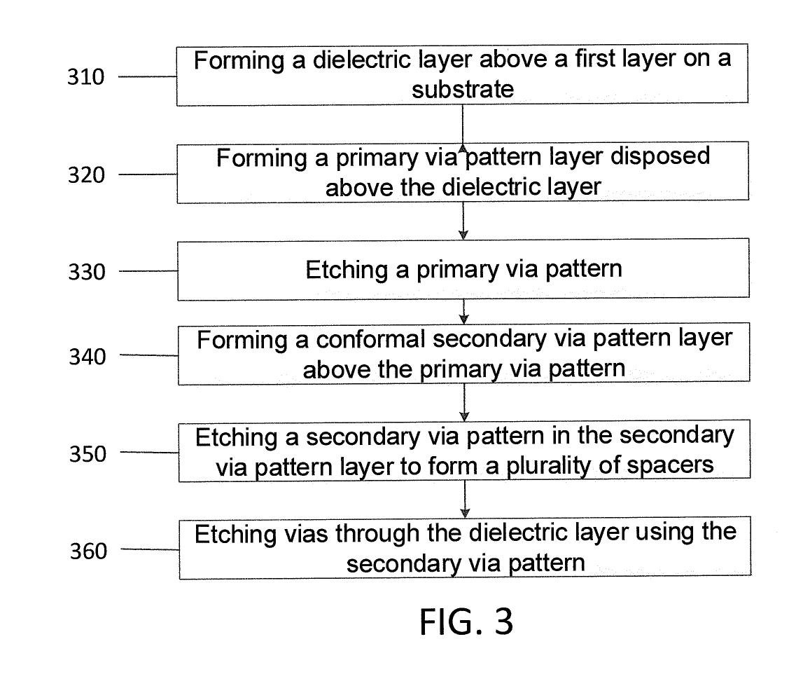

FIG. 3 is a high level flow chart illustrating a process of forming a via pattern in accordance with another embodiment of the present disclosure. In box 310, the process may begin with forming a dielectric layer above a first layer on a substrate. At box 320 the process can include forming a primary via pattern layer disposed above the dielectric layer. The primary via pattern layer may include several component layers. For example, in one embodiment, the primary via pattern layer may include a tetraethoxysilane (TEOS) layer formed over the dielectric layer, a hard mask layer formed over the TEOS layer, an organic planarization layer (OPL) formed over the hard mask layer, and a low temperature oxide (LTO) layer formed over the OPL layer.

At box 330 the process can include etching a primary via pattern in the primary via pattern layer having a plurality of via openings therethrough, the plurality of via openings having a first dimension. In one embodiment, this may include forming a photoresist on the primary via pattern layer and developing the photoresist. Any suitable process for forming the primary via pattern may be used.

At box 340 the process can include forming a conformal secondary via pattern layer above the primary via pattern. In one embodiment, this may be performed, for example, by ALD of a conformal oxide.

At box 350 the process can include etching a secondary via pattern in the secondary via pattern layer to form a plurality of spacers. The spacers are disposed on sidewalls of the plurality of via openings within the primary via pattern in the primary via pattern layer, the spacers reducing the first dimension of the plurality of via openings to a second dimension.

At box 360 the process can include etching vias through the dielectric layer using the secondary via pattern, for example, by RIE. This can include an etchback of the spacer layer to form a spacer on a plurality of sidewalls of the via pattern in the LTO layer. The process may further include etching the OPL layer through to the TEOS layer, removing the LTO layer, the spacer layer and OPL, etching the modified via pattern into the dielectric layer, and forming a plurality of conductive vias in the via pattern. The via pattern can include SAV regions and non-SAV regions. The modified via pattern can have a reduction in the critical dimension of the original via pattern between about 15% to about 55%. In some embodiments, the original critical dimension may be reduced between about 5 nm and 10 nm. The amount of reduction of the original critical dimension may be modulated and determined by the first thickness of the spacer layer.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A method of processing a semiconductor substrate, the method comprising:
forming a dielectric layer above a first layer on a substrate,
forming a primary via pattern layer disposed above the dielectric layer;
etching a primary via pattern in the primary via pattern layer having a plurality of via openings therethrough, the plurality of via openings having a first dimension;
forming a conformal secondary via pattern layer above the primary via pattern;
etching a secondary via pattern in the secondary via pattern layer to form a plurality of spacers on sidewalls of the plurality of via openings within the primary via pattern in the primary via pattern layer, the plurality of spacers reducing the first dimension of the plurality of via openings to a second dimension; and
etching via openings through the dielectric layer using the secondary via pattern.

2. The method according to claim 1, wherein forming a conformal secondary via pattern layer comprises depositing an oxide layer.

3. The method according to claim 1, wherein the primary via pattern layer comprises at least an LTO layer.

4. The method according to claim 1, wherein the primary via pattern layer further comprises a tetraethoxysilane (TEOS) layer formed over the dielectric layer, a hard mask layer formed over the TEOS layer, an organic planarization layer (OPL) formed over the hard mask layer, and a low temperature oxide (LTO) layer formed over the OPL layer.

5. The method according to claim 4, after etching the secondary via pattern layer, further comprising:
etching the OPL through to the TEOS layer.

6. The method according to claim 5, after etching the OPL, further comprising:
removing the LTO layer, the spacer layer and OPL.

7. The method according to claim 1, further comprising forming a plurality of conductive vias in the via pattern.

8. The method according to claim 1, wherein the secondary via pattern includes self-aligned via (SAV) regions and non-SAV regions.

9. The method according to claim 1, wherein the second dimension is reduced with respect to the first dimension by about 15% to about 55%.

10. The method according to claim 1, wherein the second dimension is reduced with respect to the first dimension by about 5 nm to 10 nm.

11. The method according to claim 1, wherein etching a secondary via pattern in the secondary via pattern layer comprises a reactive ion etching (RIE) process.

12. A method comprising:
forming a first low temperature oxide (LTO) layer over an organic planarization layer (OPL);
forming a primary via pattern in the LTO layer to partially expose the OPL;
forming a conformal second LTO layer over the primary via pattern including the first LTO layer and the partially exposed OPL; and
etching the second LTO layer to form a plurality of spacers on sidewalls of the primary via pattern in the first LTO layer.

13. The method according to claim 12, wherein etching the second LTO layer forms a secondary via pattern which has a reduced critical dimension with respect to the primary via pattern.

14. The method according to claim 13, wherein the secondary via pattern includes self-aligned via (SAV) regions and non-SAV regions.

15. The method according to claim 12, wherein etching the second LTO layer comprises reactive ion etching (RIE).

16. The method according to claim 12, wherein the plurality of spacers on sidewalls of the original via pattern reduce the size of openings in the primary via pattern by between about 15% to about 55%.

17. The method according to claim 12, wherein forming the first LTO layer comprises atomic layer deposition, and forming a conformal second LTO layer comprises atomic layer deposition.

18. An integrated circuit structure, comprising:
a substrate containing at least one active semiconductor device;
an interlayer dielectric layer over the substrate;
a tetraethoxysilane (TEOS) layer over the interlayer dielectric layer;
a hard mask layer over the TEOS layer;
an organic planarization layer (OPL);
a first low temperature oxide (LTO) layer over the OPL layer, the first LTO layer defining an original via pattern having a critical dimension; and
a second LTO layer over the first LTO layer defining a modified via pattern having a reduced critical dimension.

19. The integrated circuit structure of claim 18, wherein the second LTO layer is a spacer layer formed on a plurality of sidewalls of the original via pattern.

20. The integrated circuit structure of claim 18, wherein the modified via pattern includes self-aligning via (SAV) regions and non-SAV regions.
